(19) United States
(12) Patent Application Publication
(10) Pub. No.: US 2025/0147075 A1
(43) Pub. Date: May 8, 2025

(54) Current Sensor

(71) Applicant: Alps Alpine Co., Ltd., Tokyo (JP)

(72) Inventors: Manabu TAMURA, Miyagi-ken (JP); Keisuke NAKAYAMA, Miyagi-ken (JP); Hideaki TAKANO, Miyagi-ken (JP); Takashi KAWAHATA, Miyagi-ken (JP)

(21) Appl. No.: 19/014,378

(22) Filed: Jan. 9, 2025

Related U.S. Application Data
(63) Continuation of application No. PCT/JP2023/006396, filed on Feb. 22, 2023.

(30) Foreign Application Priority Data
Aug. 10, 2022 (JP) 2022-128294

(51) Int. Cl. G01R 15/20; G01R 19/00

(52) U.S. Cl. CPC G01R 15/202; G01R 15/205; G01R 19/0092

(57) ABSTRACT

A current sensor which suppresses deterioration of detection accuracy caused by high temperature of electronic components due to heat of a bus bar and is suitable for measurement of large current includes a bus bar through which a current to be measured flows, a magnetic detector detecting a magnetic field generated by the bus bar, and a case integrally formed with the bus bar and having a storage space storing the magnetic detector. The magnetic detector is spaced away from and faces the bus bar. The bus bar is on a first surface of the storage space defining the storage space and facing the magnetic detector. A low thermal conductivity material having a lower thermal conductivity than a resin-based material forming the case is provided between the bus bar and the magnetic detector to contact an opposing surface, on the bus bar, facing the magnetic detector.

### CLAIM OF PRIORITY

This application is a Continuation of International Application No. PCT/JP2023/006396 filed on Feb. 22, 2023, which claims benefit of Japanese Patent Application No. 2022-128294 filed on Aug. 10, 2022. The entire contents of each application noted above are hereby incorporated by reference.

### BACKGROUND OF THE INVENTION

### 1. Field of the Invention

The present invention relates to a current sensor which detects a magnetic field generated by a current to be measured flowing through a bus bar and measures a current value of the current to be measured using the detected magnetic field.

### 2. Description of the Related Art

In recent years, with the increasing demand for decarbonization, a shift from an engine to a motor, that is, degasolineated vehicle/electricity (EV shift), has progressed in order to control CO² emission during automobile driving, and a current sensor is used as a current measuring device to measure a current supplied to a three-phase motor, etc. (for example, Japanese Unexamined Patent Application Publication No. 2017-102024).

As the EV shift spreads to large commercial vehicles, such as trucks and buses, the motor capacity of hybrid vehicles and electric vehicles has also increased, and current to be measured of current sensors used in motor control has increased. In addition, opportunities for continuous driving under high load conditions are increasing, and current continuously being applied is increasing. The bus bar, which is a current path of a current to be measured, emits an amount of heat proportional to a square of a magnitude of the current. For this reason, as the current to be measured continuously energized increases, heat generation by the bus bar increases, and there is a problem that an electronic component, such as a magnetic detector, disposed in the vicinity of the bus bar become hot.

Japanese Unexamined Patent Application Publication No. 2017-102024 discloses a current sensor including a substrate having a magnetic detector in a case member in which a bus bar is formed by insert molding. In the current sensor, opposite surfaces of the bus bar are covered with resin in consideration of the fluidity of resin when molding is performed inside the case member. Therefore, heat generated by the bus bar is transferred to a magnetic detector through a resin-based material covering an opposing surface that faces the magnetic detector. As the current to be measured becomes larger, a heating value of the bus bar becomes larger, and a temperature in a storage space becomes higher than a heat-resistant temperature of the magnetic detector. Accordingly, there may arise problems in that measurement accuracy of the current sensor is deteriorated and a product life is shortened.

### SUMMARY OF THE INVENTION

The present invention provides a current sensor suitable for measuring a large current, in which a high temperature of an electronic component, such as the magnetic detector, due to heat generation from the bus bar is suppressed.

The present invention has the following configuration as means for solving the above-mentioned problems.

A current sensor includes a bus bar through which a current to be measured flows, a magnetic detector capable of detecting a magnetic field generated by the bus bar, and a case that is integrally formed with the bus bar and that has a storage space for storing the magnetic detector. The magnetic detector is spaced away from the bus bar and disposed in a position facing the bus bar. The bus bar is disposed on a first surface of the storage space that defines the storage space and that faces the magnetic detector in a first direction. A low thermal conductivity material having a lower thermal conductivity than a resin-based material forming the case is provided between the bus bar and the magnetic detector to contact an opposing surface, on the bus bar, that faces the magnetic detector.

Heat emitted by the bus bar is difficult to be transferred to the magnetic detector via the storage space due to the low thermal conductivity material provided between the bus bar and the magnetic detector, and therefore, heat transmitted from the bus bar to the magnetic detector may be reduced. Accordingly, deterioration of detection accuracy of the magnetic sensor caused by a high temperature in a portion near the magnetic detector due to the heat of the bus bar may be suppressed.

Only an air layer may be provided between the bus bar and the magnetic detector as the low thermal conductivity material.

The thermal conductivity of air is relatively low, and the air layer is a good insulation layer. Therefore, rise in temperature around the magnetic detector may be suppressed by a simple configuration in which the air layer is provided between the bus bar and the magnetic detector. Air included in the air layer may be a low thermal conductivity material provided so as to be adjacent to the opposing surface.

The bus bar may have the opposing surface exposed in the storage space and an opposite surface that is located on an opposite side of the opposing surface and that is buried in the case.

In a region in which the bus bar and the magnetic detector face each other, heat transferred from the opposing surface of the bus bar to the magnetic detector through the storage space may be reduced by air between the opposing surface of the bus bar and the magnetic detector. Moreover, by burying the opposite surface of the bus bar in the region in the case having a higher thermal conductivity than air, the heat of the bus bar may be directed to the case positioned on an opposite side of the magnetic detector. Therefore, it is possible to suppress the temperature around the magnetic detector from becoming high due to the heat of the bus bar.

A distance in the first direction between the opposing surface of the bus bar and the magnetic detector may be less than or equal to a distance in the first direction between the first surface of the storage space and the magnetic detector.

When a distance from the magnetic detector to the opposing surface of the bus bar is larger than a distance from the magnetic detector to the first surface of the storage space in the first direction, the heat of the bus bar to be transmitted from the first surface of the storage space via the storage space to the magnetic detector may be reduced so that increase in temperature near the magnetic detector may be suppressed.

The opposing surface of the bus bar and the first surface of the storage space may form the same plane.

The case and the bus bar are formed and processed easily when the opposing surfaces of the bus bar and the first surface of the storage space are on the same plane.

The current sensor may further include a magnetic shield.

The magnetic shield may be a pair of flat plate-shaped magnetic shields arranged in the first direction, and the bus bar and the magnetic detector may be arranged between the pair of flat plate-shaped magnetic shields.

The flat-plate shaped magnetic shields disposed proximal to the bus bar is integrally formed with the case together with the bus bar.

Since external magnetic field noise to the magnetic detector may be blocked by the magnetic shield, the immunity to external magnetic field noise of the magnetic detector is improved.

The magnetic shield may have a base portion disposed on an opposite side of the magnetic detector in the first direction across the bus bar and a sidewall portion extending in the first direction from individual ends of the base portion.

When a cross-sectional U-shaped magnetic shield is disposed around the bus bar, the immunity of the current sensor to the external magnetic field noise is improved.

The magnetic detector may include a first magnetic detector and a second magnetic detector, and may be capable of detecting a magnetic field generated by the bus bar based on an output of the first magnetic detector and an output of the second magnetic detector.

When the magnetic field is detected based on outputs of the first and second magnetic detectors, the influence of external magnetic field noise common to the first and second magnetic detectors may be removed, and therefore, the immunity of the current sensor to the external magnetic field noise is improved.

In a cross-sectional shape of the bus bar that is orthogonal to an extending direction of the bus bar, a dimension in the first direction may be larger than a dimension in a second direction that is orthogonal to the first direction.

When the bus bar having a cross-sectional shape in which the dimension in the first direction is larger than the dimension in the second direction is used, an elongated oval magnetic field is generated in the cross section with a major axis having a component in the first direction larger than a component in the second direction. Therefore, near the magnetic detector, a component in the first direction may be large, a magnetic field in an opposite direction may be formed, and a magnetic field generated by the bus bar may be detected with high accuracy.

The magnetic detector may include an output terminal portion, the output terminal portion may be held on a substrate, and the output terminal portion may be sealed.

When the output terminal portion is sealed by potting with a sealing agent, discharge from the bus bar to the output terminal portion is less likely to occur, and the voltage resistance of the current sensor is improved.

A cover covering the storage space may be included, the magnetic detector may include an output terminal portion, the output terminal portion may be held on the substrate, and the substrate may be held by the cover.

When the heat of the bus bar is transferred to the substrate via the resin-based material, the heat transfer property is deteriorated at a contact portion between the case and the cover, and accordingly, increase in temperature in the magnetic detector caused by heat of the bus bar transmitted to the magnetic detector may be suppressed.

### BRIEF DESCRIPTION OF THE DRAWINGS

FIG. 1 is a perspective view of a current sensor according to an embodiment of the present invention;

FIG. 2 is a cross-sectional view of the current sensor according to a first embodiment taken along a line II to II in FIG. 1;

FIG. 3 is a plan view of the current sensor of FIG. 2;

FIG. 4 is a cross-sectional view of a modification of the current sensor according to the first embodiment;

FIG. 5 is a cross-sectional view of another modification of the current sensor according to the first embodiment;

FIG. 6 is a cross-sectional view of a current sensor according to a second embodiment;

FIG. 7 is a cross-sectional view of a modification of the current sensor according to the second embodiment;

FIG. 8 is a cross-sectional view of a current sensor according to a third embodiment;

FIG. 9 is a cross-sectional view of a current sensor according to a fourth embodiment;

FIG. 10 is a cross-sectional view of a current sensor according to a fifth embodiment;

FIG. 11 is a cross-sectional view of a current sensor according to a sixth embodiment; and

FIG. 12 is a cross-sectional view of a current sensor of the related art.

### DESCRIPTION OF THE PREFERRED EMBODIMENTS

Hereinafter, an embodiment of the present invention will be described with reference to the accompanying drawings. In the individual drawings, the same reference numerals are given to the same components, and descriptions thereof are omitted accordingly. Reference coordinates are illustrated in the individual drawings as appropriate to indicate the positional relationship among individual members. In the reference coordinates, a direction of installation of a bus bar corresponds to an X-axis direction, a direction orthogonal to the X-axis direction in a plate surface of the bus bar corresponds to a Y-axis direction, and a vertical line direction on the plate surface of the bus bar corresponds to a Z-axis direction.

### FIRST EMBODIMENT

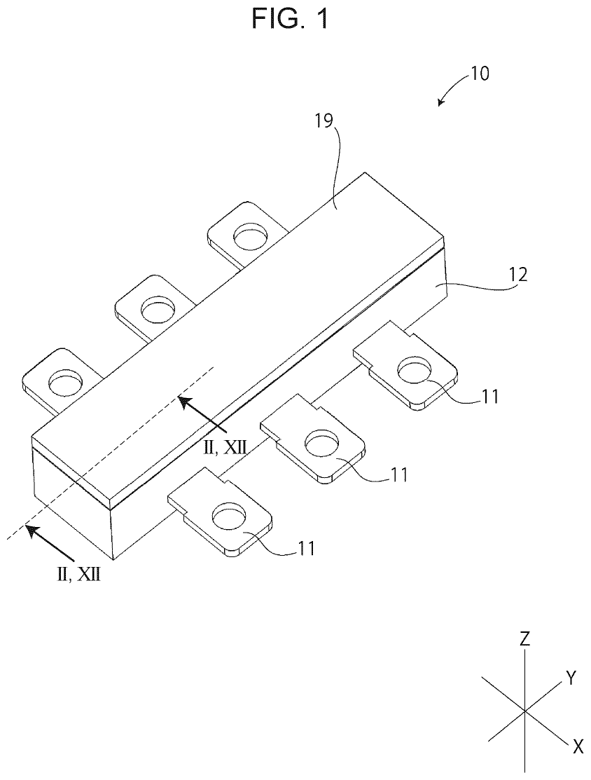

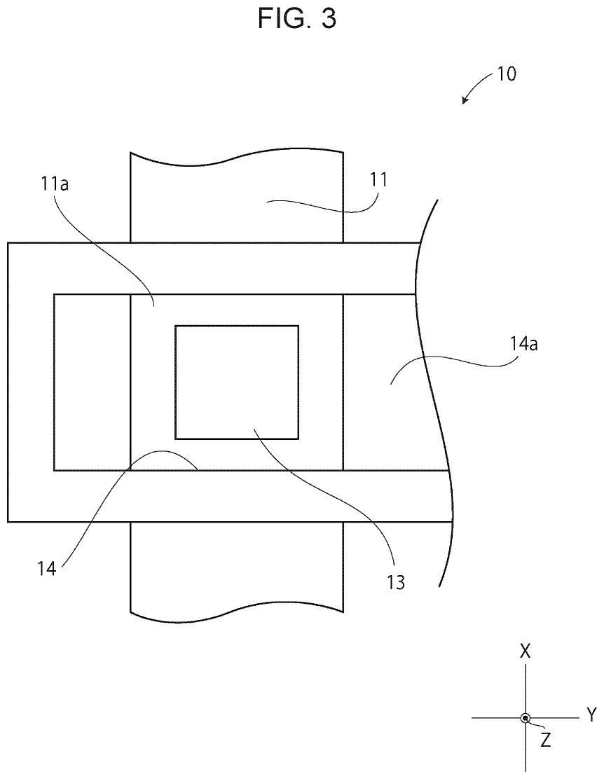

FIG. 1 is a perspective view of a current sensor 10 according to a first embodiment. The current sensor 10 has three bus bars 11 integrally formed with a case member 12, three magnetic detectors 13 (refer to FIG. 3) on a substrate 19, and three measurement channels. Note that the present invention may also be implemented as a current sensor having a single or a plurality of measurement channels other than three.

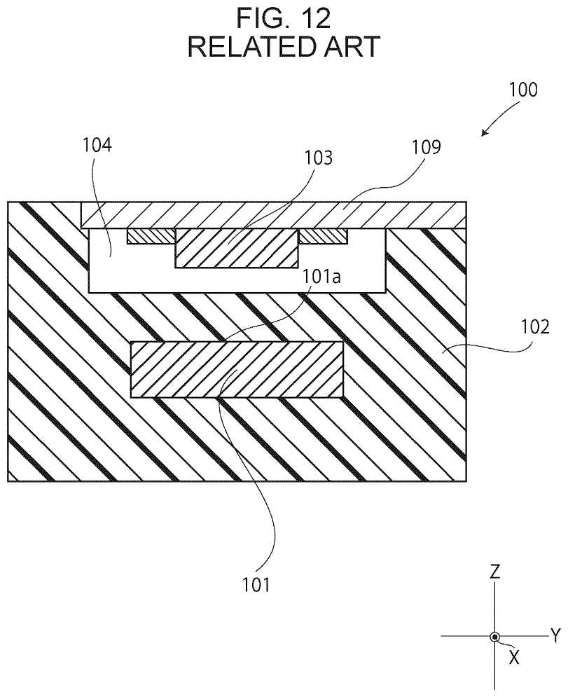

FIG. 12 is a cross-sectional view of a conventional current sensor 100, illustrating a cross section of a portion including a set of a bus bar 101 and a magnetic detector 103, which corresponds to a case where cutting is performed in a YZ plane in a line XII to XII in FIG. 1. As illustrated in the same figure, in the current sensor 100, resin-based materials are disposed on opposite sides in the Z-axis direction of the bus bar 101 in consideration of the fluidity of the resin-based materials when insert molding is performed for the bus bar 101 into a case member 102. Thus, in the conventional current sensor 100, a resin-based material of the case member 102 is formed between the bus bar 101 and the magnetic detector 103, and the bus bar 101 is not exposed in a storage space 104 of the magnetic detector 103.

The thermal conductivity of the resin-based material forming the case member 102 is larger than that of air. For example, a thermal conductivity of polyphenylene sulfide (PPS) is approximately 0.3 W/mK, which is greater than a thermal conductivity of air at 0.0241 W/mK. The conventional current sensor 100 has a resin-based material that is more likely to transfer heat generated by the bus bar 101 than air and that is positioned between the bus bar 101 and the magnetic detector 103. Therefore, the heat generated by the bus bar 101 is easily transmitted through a resin layer of the resin-based material to a position close to the magnetic detector 103, and accordingly, a temperature around the magnetic detector 103 is easily raised. Furthermore, since heat is easily transferred from the resin-based material to a side wall of the case member 102, the heat is easily transferred to the magnetic detector 103 through the case member 102 and a substrate 109. Accordingly, when the current to be measured flowing through the bus bar 101 becomes large current, and therefore, a heat amount becomes large, the magnetic detector 103 may become high temperature and exceed a heat resistance temperature.

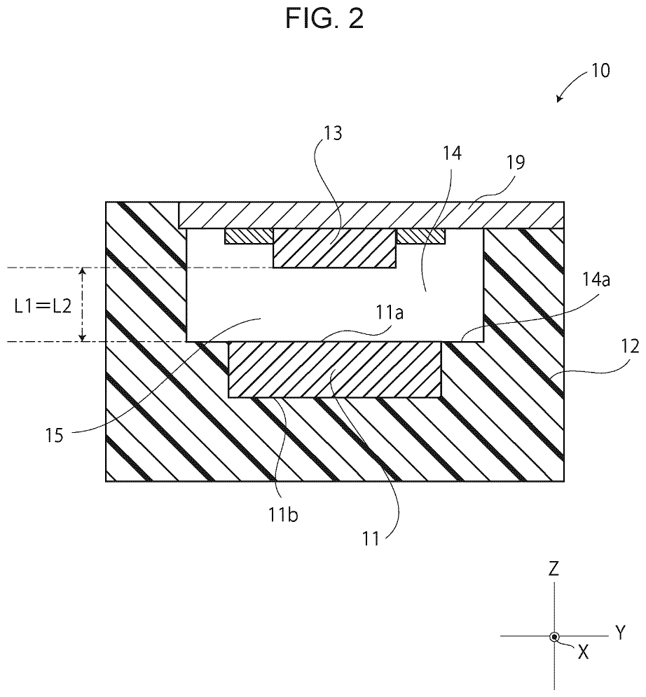

FIG. 2 is a cross-sectional view of the current sensor 10 according to this embodiment cut in a YZ plane at the line II to II of FIG. 1. FIG. 3 is a plan view of the current sensor 10 of FIG. 2. In FIG. 3, terminals of the magnetic detector 13 and the substrate 19 are omitted in order to illustrate the positional relationship among the bus bars 11, the case member 12, and the magnetic detectors 13 when viewed from the substrate 19 toward the bus bars 11 along the Z axis.

The current sensor 10 includes the bus bars 11, the case member 12, and the magnetic detectors 13.

Each of the bus bars 11 is a conductive material formed in a plate shape, a portion of which is integrally formed with the case member 12 by insert molding. The bus bars 11 are formed of, for example, copper, brass, aluminum, etc., through which the current to be detected flows. Each of the bus bars 11 is disposed so that two opposite plate surfaces correspond to upper and lower sides (opposite sides in the Z-axis direction) of the case member 12, respectively.

Note that two end portions of each of the bus bars 11 which are connection portions with an outside in the X-axis direction may not be linearly symmetrical with respect to the Y-axis. In addition, in each of the bus bars 11, a portion that faces a corresponding one of the magnetic detectors 13 may have a smaller dimension in the Y-axis direction than the other portions. Each of the bus bars 11 may not have a flat plate shape except for the portion opposite the magnetic detector 13, and may be subjected to, for example, bending processing.

The magnetic detector 13 is spaced away from the bus bar 11 and disposed in a position facing the bus bar 11. In FIG. 3, when viewed along the Z-axis, a center of a width in the Y-axis direction of the magnetic detector 13 and a center of a width in the Y-axis direction of the bus bar 11 are arranged so as to overlap with each other. However, the magnetic detector 13 is disposed at least in a position where a magnetic field generated when a current to be measured flows through the bus bar 11 may be measured. Therefore, the entire magnetic detector 13 may be arranged in a shifted position instead of a position overlapping with the bus bar 11. However, it is preferable that a portion of the magnetic detector 13 overlaps with the opposing bus bar 11 when viewed along the Z axis.

The current sensor 10 fixes the substrate 19 having the magnetic detectors 13 mounted thereon with respect to the case member 12 having the bus bars 11 formed by insert molding. Therefore, positioning between the bus bars 11 and the magnetic detectors 13 can be performed with high accuracy.

A portion of the bus bar 11 is buried in a first surface 14a of a storage space 14. The first surface 14a is a portion of a surface defining the storage space 14, and faces the magnetic detector 13 along a first direction (Z-axis direction). Since an opposing surface 11a of the bus bar 11 facing the magnetic detector 13 is exposed in the first surface 14a, there is air as a low thermal conductivity material between the bus bar 11 and the magnetic detector 13, and air abuts the opposing surface 11a. The opposing surface 11a of the bus bar 11 in the current sensor 10 abuts air as a low thermal conductivity material on its entire surface.

In the current sensor 10, only an air layer 15 is provided between the opposing surface 11a of the bus bar 11 and the magnetic detector 13. Air has a lower thermal conductivity than the resin-based material forming the case member 12. By contacting the air layer 15 with the opposing surface 11a of the bus bar 11, heat of the bus bar 11 is difficult to be transferred directly across the storage space 14 to the magnetic detector 13. In addition, since it is difficult for heat to be transferred from the opposing surface 11a of the bus bar 11 to the sidewall portions of the storage space 14, heat transferred to the magnetic detector 13 through the sidewall portions of the storage space 14 and the substrate 19 may also be reduced compared with the conventional current sensor 100 (refer to FIG. 12). Therefore, the influence of the heat of the bus bar 11 is reduced, and a temperature around the magnetic detector 13 may be kept low compared with the conventional current sensor 100. Therefore, the current to be measured which is to energize the bus bars 11 may be increased. Note that examples of the resin-based material include materials formed of resin and materials to which fillers and the like are added.

The bus bar 11 has the exposed opposing surface 11a facing the magnetic detector 13 in the storage space 14, and an opposite surface 11b on an opposite side of the opposing surface 11a is buried in the case member 12. From the viewpoint of suppression of transfer of heat of the bus bar 11 from the opposing surface 11a to the magnetic detector 13, it is preferable to expose the entire surface of the opposing surface 11a in the bus bar 11 and to have the entire surface of the opposite surface 11b buried in the case member 12.

From the viewpoint of improvement of the manufacturing efficiency by making the case member 12 and the bus bar 11 easier to be formed and processed, it is preferable that the opposing surfaces 11a of the bus bar 11 and the first surface 14a of storage space 14 form the same plane.

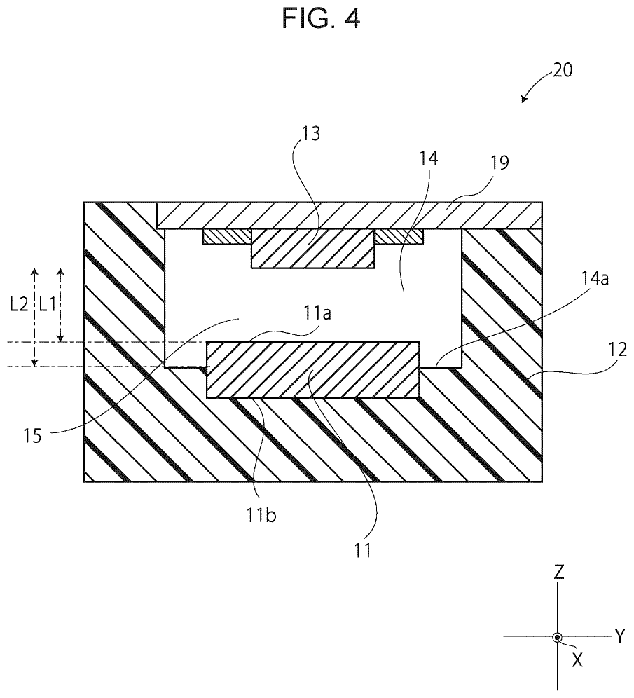

FIG. 4 is a cross-sectional view of a modification of a current sensor. A current sensor 20 according to the modification is different from the current sensor 10 in that an opposing surface 11a and a first surface 14a do not form the same plane.

In the current sensor 10 illustrated in FIG. 2, a distance L1 in the first direction (Z-axis direction) between the opposing surface 11a of the bus bar 11 and the magnetic detector 13 and a distance L2 in the first direction (Z-axis direction) between the first surface 14a of the storage space 14 and the magnetic detector 13 are equal to each other. In contrast, in the current sensor 20 illustrated in FIG. 4, a distance L1 between the opposing surface 11a of a bus bar 11 and a magnetic detector 13 is smaller than a distance L2 between the first surface 14a of the storage space 14 and the magnetic detector 13. When the distance L1 is smaller than the distance L2, the heat of the bus bar 11 transmitted to the magnetic detector 13 through the resin-based material of the case member 12 may be reduced.

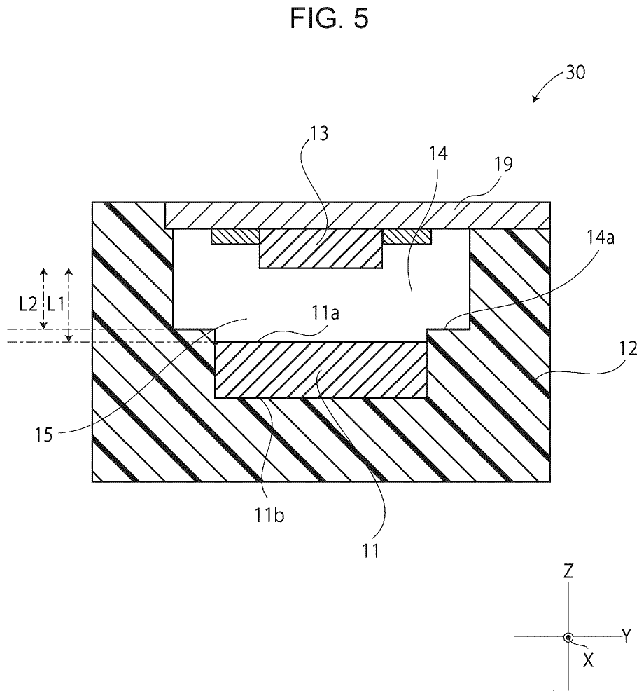

FIG. 5 is a cross-sectional view of another modification of a current sensor. In a current sensor 30 according to the other modification, a distance L1 between an opposing surface 11a of a bus bar 11 and a magnetic detector 13 is larger than a distance L2 between a first surface 14a of a storage space 14 and a magnetic detector 13. However, because the entire surface of the opposing surface 11a of the bus bar 11 is exposed in the storage space 14, air acts as a low thermal conductivity material so that transfer of heat of the bus bar 11 to the magnetic detector 13 may be suppressed.

### SECOND EMBODIMENT

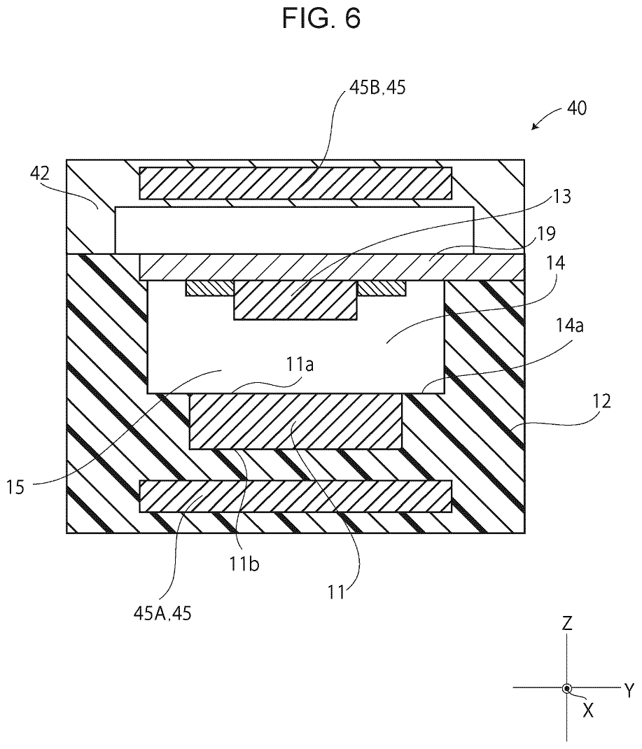

FIG. 6 is a cross-sectional view of a current sensor 40 according to this embodiment. The current sensor 40 is different from the current sensor 10 in a configuration in which a magnetic shield 45 is disposed.

The magnetic shield 45 includes a pair of flat-plate shaped magnetic shields 45A and 45B aligned in the Z-axis direction. A magnetic detector 13 and a bus bar 11 are arranged between the magnetic shield 45A and the magnetic shield 45B in the Z-axis direction.

The magnetic shield 45A positioned proximally of the bus bar 11 is formed integrally with a case member 12 together with the bus bar 11, and is provided on an opposite side from a side on which the magnetic detector 13 is disposed with respect to the bus bar 11.

The magnetic shield 45B positioned proximally of the magnetic detector 13 is formed integrally with a cover member 42 and is provided opposite to a side on which the bus bar 11 is arranged with respect to the magnetic detector 13.

The magnetic shields 45A and 45B are, for example, made of a plurality of metal plate-like bodies of the same shape superimposed on one another. Since external magnetic field noise may be blocked by the magnetic shields 45A and 45B, the immunity of the external magnetic field noise of the magnetic detector 13 is improved. Note that only one of the magnetic shields 45A and 45B may be provided instead of the pair because an effect of blocking external magnetic field noise is attained by only one of the magnetic shields 45A and 45B.

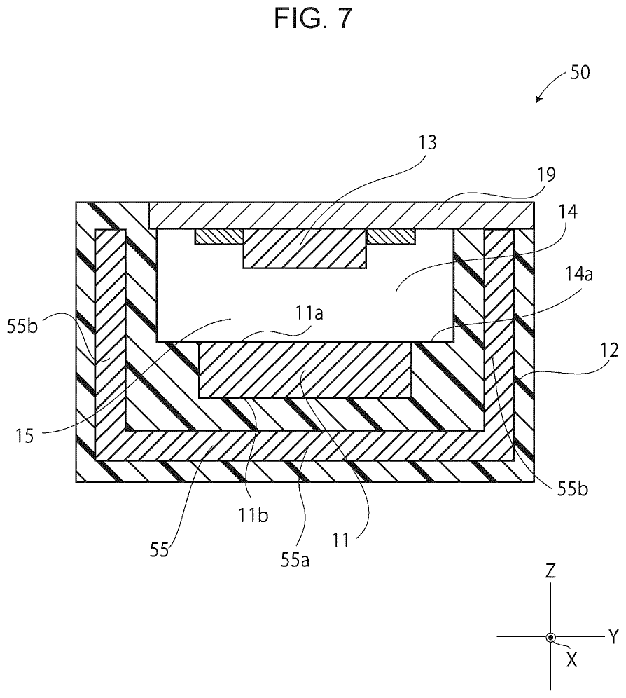

FIG. 7 is a cross-sectional view of a modification of the current sensor according to this embodiment. A current sensor 50 according to the modification is different from the current sensor 40 in that the current sensor 50 includes a magnetic shield 55 in which a cross-sectional surface of a YZ plane perpendicular to a direction of extension (X-axis direction) of the bus bar 11 is U-shaped so as to surround the bus bar 11 and the magnetic detector 13.

The magnetic shield 55 has a base portion 55a disposed opposite the magnetic detector 13 of the bus bar 11, and sidewall portions 55b extending along the Z-axis direction from respective ends of the base portion 55a. The magnetic shield 55 is arranged so as to surround the bus bar 11 and the magnetic detector 13, that is, the bus bar 11 and the magnetic detector 13 overlap the base portion 55a when viewed in the Z-axis direction, and the bus bar 11 and the magnetic detector 13 overlap the sidewall portions 55b when viewed in the Y-axis direction. Therefore, external magnetic field noise to the bus bar 11 and the magnetic detector 13 may be effectively blocked by the magnetic shield 55, and the immunity of the external magnetic field noise of the current sensor 50 is improved.

### THIRD EMBODIMENT

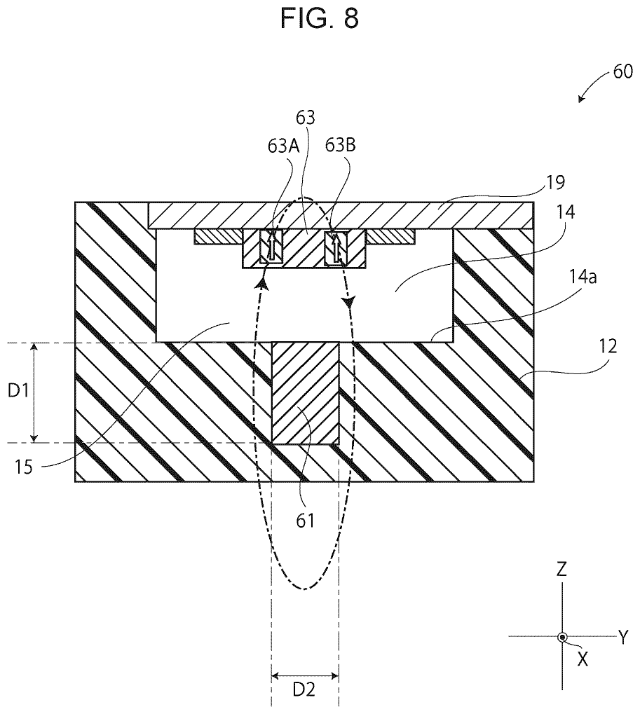

FIG. 8 is a cross-sectional view of a current sensor 60 according to this embodiment. The current sensor 60 is different from the current sensor 10 in a shape of a bus bar 61 and in a configuration in which a magnetic detector 63 performs differential detection.

The current sensor 60 includes a first magnetic detector 63A and a second magnetic detector 63B as a magnetic detector 63, and a magnetic field generated by the bus bar 61 may be detected based on outputs of the first magnetic detector 63A and the second magnetic detector 63B. As the first magnetic detector 63A and the second magnetic detector 63B, Hall elements and magnetoresistive elements (GMR elements, TMR elements, etc.) having detection axes in the same or opposite directions in the Z-axis direction are used.

The bus bar 61 of this embodiment has, in a cross-sectional shape orthogonal to an extension direction (X-axis direction), a dimension D1 in the Z-axis direction (first direction) which is larger than a dimension D2 in the Y-axis direction (second direction) orthogonal to the Z-axis direction. That is, the bus bar 61 has a plate-like shape with a narrow width in the Y-axis direction compared to a width in the Z-axis direction. Therefore, when a current to be measured flows, as illustrated using a single point chain line in FIG. 8, a magnetic field of an elongated oval is generated which has a component in the Z-axis direction (first direction) with a long axis larger than a component in the Y-axis direction (second direction). Therefore, near the magnetic detector 63, a magnetic field having the components which are large in the first direction (Z-axis direction) and which face opposite directions may be formed. However, in place of the bus bar 61 whose dimension D1 is larger than the dimension D2 (dimension D1 >dimension D2), a bus bar whose dimension D1 is less than or equal to the dimension D2 (dimension D1≤dimension D2) may be used.

In the differential current sensor 60, the first magnetic detector 63A and the second magnetic detector 63B, which show strong sensitivity to a magnetic field in a specific direction (sensitivity direction), are used as the magnetic detector 63. The first magnetic detector 63A and the second magnetic detector 63B are arranged so that the sensitivity directions thereof are approximately parallel. In addition, the first magnetic detector 63A and the second magnetic detector 63B are arranged in a posture in which the sensitivity directions are approximately parallel to directions of magnetic fields in positions where directions of the magnetic fields caused by the current to be measured are approximately opposite to each other so that a high measurement sensitivity may be obtained.

The magnetic fields of the current to be measured in the positions where the pair of the first magnetic detector 63A and the second magnetic detector 63B are arranged are opposite in directions of vectors, and a difference of the magnetic fields as a vector is large. In the differential current sensor 60, a measurement result of the current is obtained based on a magnetic field as a vector detected between the first magnetic detector 63A and the second magnetic detector 63B.

As illustrated by white arrows in FIG. 8, when the sensitivity directions of the first magnetic detector 63A and the second magnetic detector 63B are the same, a measurement result of the current is obtained based on a difference between two detected signals of the first magnetic detector 63A and the second magnetic detector 63B. When the sensitivity directions of the first magnetic detector 63A and the second magnetic detector 63B are opposite to each other, a measurement result of the current is obtained based on a sum of two detected signals of the first magnetic detector 63A and the second magnetic detector 63B.

The influence of external magnetic field noise common to the first magnetic detector 63A and the second magnetic detector 63B may be removed by detecting the magnetic field of the bus bar 61 based on the outputs of the first magnetic detector 63A and the second magnetic detector 63B. Therefore, induced magnetic fields of the bus bars 61 may be detected with high accuracy by the current sensor 60.

### FOURTH EMBODIMENT

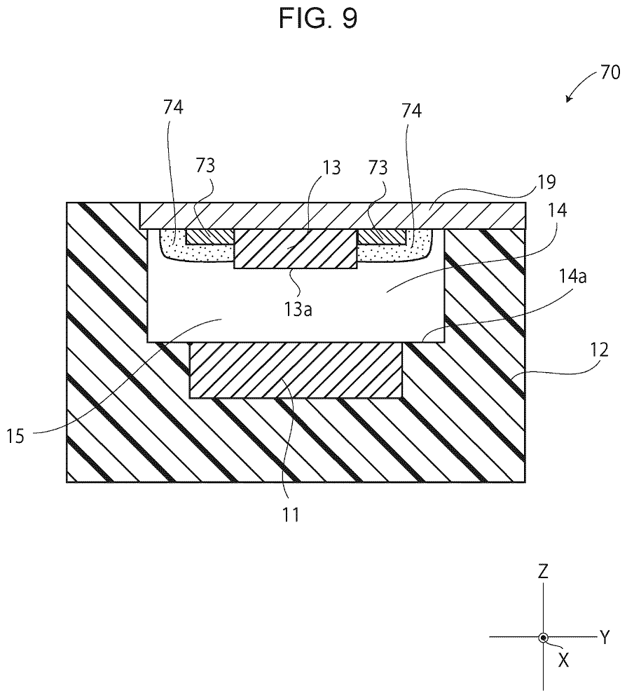

FIG. 9 is a cross-sectional view of a current sensor 70 according to this embodiment. The current sensor 70 is different from the current sensor 10 in a configuration in which a magnetic detector 13 includes output terminal portions 73, the output terminal portions 73 are held on a substrate 19, and the output terminal portions 73 are sealed by sealing agents 74. By potting and sealing the output terminal portions 73 with the sealing agents 74, discharge from a bus bar 11 to the output terminal portions 73 is less likely to occur, and voltage resistance of the current sensor 70 is improved.

The sealing agents 74 are provided so as to cover the output terminal portions (electrode terminals) 73 and not to cover an opposing surface 13a of the magnetic detector 13 that faces the bus bar 11. Therefore, heat of the bus bar 11 transmitted to the magnetic detector 13 through the sealing agents 74, which have a higher thermal conductivity than air in a storage space 14, may be suppressed. Therefore, increase in temperature of the magnetic detector 13 caused by heat of the bus bar 11 may be suppressed.

### FIFTH EMBODIMENT

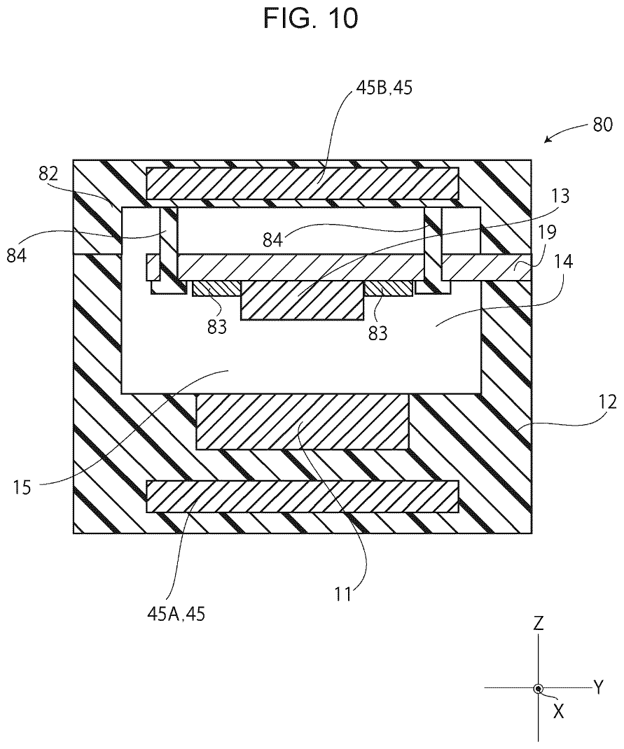

FIG. 10 is a cross-sectional view of a current sensor 80 according to this embodiment.

The current sensor 80 includes a cover member 82 covering a storage space 14, a magnetic detector 13 includes output terminal portions 83, the output terminal portions 83 are held on a substrate 19, and holding members 84 are disposed to hold the substrate 19 on the cover member 82.

When the heat of the bus bar 11 is transferred to the substrate 19 through a resin-based material constituting a case member 12 and the cover member 82, a heat transfer property is deteriorated at a contact portion between the case member 12 and the cover member 82. In addition, the substrate 19 is held in the cover member 82 through the holding members 84, and since a layer of air is formed between the substrate 19 and the cover member 82, heat is not easily transferred from the cover member 82 to the substrate 19. In addition, a path of heat transfer through the resin-based material becomes longer. Therefore, increase in temperature of the magnetic detector 13 caused by the heat of the bus bar 11 may be suppressed.

### SIXTH EMBODIMENT

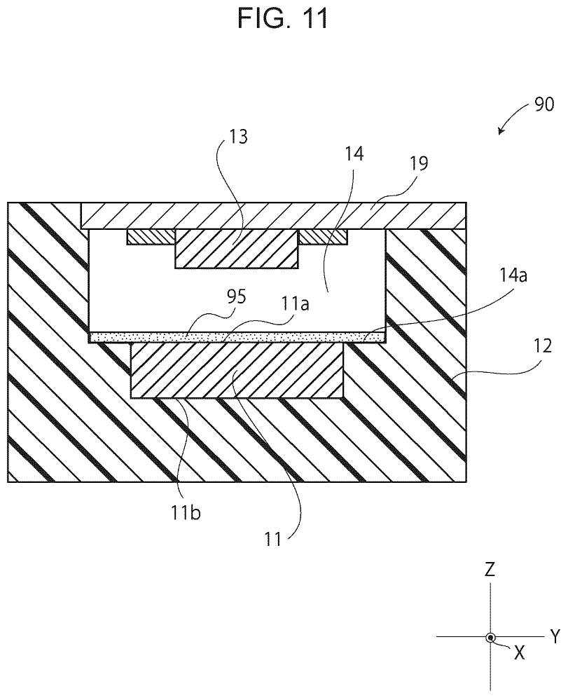

FIG. 11 is a cross-sectional view of a current sensor 90 according to this embodiment.

The current sensor 90 is different from the current sensor 10 in a configuration in which a low thermal conductivity material 95 other than the air layer 15 (refer to FIG. 2) is provided so as to abut an opposing surface 11a of a bus bar 11.

By providing the low thermal conductivity material 95 having a lower thermal conductivity than a resin-based material forming a case member 12, increase in temperature of a magnetic detector 13 caused by propagation of the heat of the bus bar 11 to the magnetic detector 13 may be suppressed.

Porous ceramics and the like may be used as the low thermal conductivity material 95. A thermal conductivity of porous ceramics varies depending on a type of the porous ceramics but is approximately 0.003 W/mK. This value is slightly larger than the thermal conductivity of air but is sufficiently smaller than the thermal conductivity of resin-based materials, such as polyphenylene sulfide. Therefore, by providing the low thermal conductivity material 95, the heat transferred from the bus bar 11 to the magnetic detector 13 may be reduced similarly to the layer of air.

Note that the low thermal conductivity material 95 may not cover an entire opposing surface 11a of the bus bar 11 and a first surface 14a of a storage space 14, as illustrated in FIG. 11. For example, the low thermal conductivity material 95 may be provided so as to cover only the opposing surface 11a. Furthermore, a region on the opposing surface 11a of the bus bar 11 may be covered by the low thermal conductivity material 95 and the other region may be covered by an air layer 15.

The embodiments disclosed herein are exemplary in all respects, and the present disclosure is not limited to these embodiments. The scope of the invention is shown by the scope of the claims rather than by the description of the above-described embodiment only, and it is intended to include all changes within the same meaning and scope as the scope of the claims.

### EXAMPLES

As for the current sensor 10 according to the first embodiment illustrated in FIG. 2, the ease of heat transfer from the bus bar 11 to the magnetic detector 13 is simulated. Furthermore, with respect to the conventional current sensor 100 illustrated in FIG. 12, the ease of heat transfer from the bus bar 101 to the magnetic detector 103 is simulated. In these simulations, current to be measured which is continuously energized is set to 200 A, and temperatures of the magnetic detectors 13 and 103 at a time when temperatures of the bus bars 11 and 101 become 146° C. are obtained.

The current sensor 10 is evaluated with respect to the one in which an entire surface of the opposing surface 11a of the bus bar 11 is exposed, and the distance L1 and the distance L2 in the Z-axis direction between the opposing surface 11a of the bus bar 11 and the magnetic detector 13 are 4.2 mm. The conventional current sensor 100 is different from the current sensor 10 only in the configuration in which the entire surface of the opposing surface 101a of the bus bar 101 is covered by the resin-based material having a thickness of 1.2 mm, and is evaluated with respect to the one in which the distance L1 is 3.0 mm and the distance L2 is 1.2 mm. The resin-based material constituting the case member 12 and the case member 102 is polyphenylene sulfide (PPS).

As a result of the simulations, a temperature of the magnetic detector 13 of the current sensor 10 is 121.8° C., while a temperature of the magnetic detector 103 of the current sensor 100 is 129.0° C. Thus, according to the present invention in which the resin-based material is removed from the opposing surface 11a of the bus bar 11 so that the opposing surface 11a is exposed, increase in temperature of the magnetic detector 13 due to the influence of the heat of the bus bar 11 may be suppressed. From the results of these simulations, it can be seen that the current sensor 10 of the present invention may use the magnetic detector 13 having a heat-resistant temperature of 125° C. that may not be used in the conventional current sensor 100.

The present invention is useful as a current sensor having bus bars through which a large current flows as a current to be measured.

What is claimed is:

1. A magnetic sensor comprising:
a bus bar through which a current to be measured flows;
a magnetic detector capable of detecting a magnetic field generated by the bus bar; and
a case that is integrally formed with the bus bar and that has a storage space for storing the magnetic detector, wherein
the magnetic detector is spaced away from the bus bar and disposed in a position facing the bus bar,
the bus bar is disposed on a first surface of the storage space that defines the storage space and that faces the magnetic detector in a first direction,
a low thermal conductivity material having a lower thermal conductivity than a resin-based material forming the case is provided between the bus bar and the magnetic detector to contact an opposing surface, on the bus bar, that faces the magnetic detector,
the magnetic detector includes an output terminal portion,
the output terminal portion is held on a substrate, and
the output terminal portion is sealed by a sealing agent having a higher thermal conductivity than air, and the sealing agent does not cover an opposing surface of the magnetic detector that faces the bus bar.

2. The current sensor according to claim 1, wherein only an air layer is provided between the bus bar and the magnetic detector as the low thermal conductivity material.

3. The current sensor according to claim 2, wherein the bus bar has the opposing surface exposed in the storage space and an opposite surface that is located on an opposite side of the opposing surface and that is buried in the case.

4. The current sensor according to claim 3, wherein a distance in the first direction between the opposing surface of the bus bar and the magnetic detector is less than or equal to a distance in the first direction between the first surface of the storage space and the magnetic detector.

5. The current sensor according to claim 3, wherein the opposing surface of the bus bar and the first surface of the storage space form the same plane.

6. The current sensor according to claim 1, further comprising a magnetic shield.

7. The current sensor according to claim 6, wherein
the magnetic shield is a pair of flat-plate shaped magnetic shields arranged in the first direction, and
the bus bar and the magnetic detector are arranged between the pair of flat-plate shaped magnetic shields.

8. The current sensor according to claim 7, wherein one of the flat-plate shaped magnetic shields that is disposed proximal to the bus bar is integrally formed with the case together with the bus bar.

9. The current sensor according to claim 6, wherein the magnetic shield has a base portion disposed on an opposite side of the magnetic detector in the first direction across the bus bar and sidewall portions extending in the first direction from individual ends of the base portion.

10. The current sensor according to claim 1, wherein the magnetic detector includes a first magnetic detector and a second magnetic detector, and is capable of detecting a magnetic field generated by the bus bar based on an output of the first magnetic detector and an output of the second magnetic detector.

11. The current sensor according to claim 10, wherein, in a cross-sectional shape of the bus bar that is orthogonal to an extending direction of the bus bar, a dimension in the first direction is larger than a dimension in a second direction that is orthogonal to the first direction.

12. The magnetic sensor according to claim 1, further comprising:
a cover that covers the storage space, wherein
the magnetic detector includes an output terminal portion,
the output terminal portion is held on a substrate, and the substrate is held on the cover.
